(19) United States
(12) Patent Application Publication
(10) Pub. No.: US 2025/0199398 A1
(43) Pub. Date: Jun. 19, 2025

(54) INSPECTION SYSTEM AND METHOD FOR OPERATING THEREOF

(71) Applicant: TAIWAN SEMICONDUCTOR MANUFACTURING COMPANY, LTD., Hsinchu (TW)

(72) Inventors: Chao-Ting CHEN, Taichung City (TW); Chih-Feng LU, New Taipei City (TW); Yen-Hsun CHEN, Taipei City (TW); Shang-Chieh CHIEN, New Taipei City (TW); Li-Jui CHEN, Hsinchu City (TW)

(73) Assignee: TAIWAN SEMICONDUCTOR MANUFACTURING COMPANY, LTD., Hsinchu (TW)

(21) Appl. No.: 18/403,455

(22) Filed: Jan. 3, 2024

Related U.S. Application Data
(60) Provisional application No. 63/611,204, filed on Dec. 17, 2023.

(51) Int. Cl. G03F 1/84; G01N 21/956

(52) U.S. Cl. CPC G03F 1/84; G01N 21/95607; G01N 2021/95615; G01N 2021/95676

(57) ABSTRACT

A method includes capturing a first reference image of a mask by an inspection apparatus, the capturing comprising measuring a first reflected light intensity from the first reference image; performing, using the mask, an exposure process on a wafer; after performing the exposure process, measuring a second reflected light intensity on the mask by the inspection apparatus; comparing the second reflected light intensity with the first reflected light intensity from the first reference image; determining whether a first comparison result of the first and second reflected light intensities is acceptable; in response to the determination determines that the first comparison result is unacceptable, adjusting an inspection parameter of the inspection apparatus.

### PRIORITY CLAIM AND CROSS-REFERENCE

This application claims priority to U.S. Provisional Application Ser. No. 63/611,204, filed Dec. 17, 2023, which is herein incorporated by reference.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flow chart of a method including operations of a mask, in accordance with some embodiments of the present disclosure.

FIG. 2A illustrates a schematic view of one stage of a method for capturing an image of a mask in an inspection apparatus prior to performing an exposure process on the mask, in accordance with some embodiments of the present disclosure.

FIG. 2B illustrates a schematic view of a mask in accordance with some embodiments of the present disclosure.

FIG. 2C illustrates a schematic view of a reference image captured from a mask by an inspection apparatus, in accordance with some embodiments of the present disclosure.

FIG. 3 illustrates a schematic view of one stage of a method for operating a mask in a lithography exposure system, in accordance with some embodiments of the present disclosure.

FIG. 4 illustrates a schematic view of one stage of a method for operating a parameter comparison of an inspection apparatus based on a mask after performing an exposure process on the mask, in accordance with some embodiments of the present disclosure.

FIGS. 5A and 5B illustrate schematic views of one stage of a method for performing compensations on an inspection apparatus based on a mask, in accordance with some embodiments of the present disclosure.

FIG. 5C shows a multi-error versus mask to mask reflection (MMR) plot of an inspection apparatus based on a mask, in accordance with some embodiments of the present disclosure.

FIG. 5D illustrates a schematic view of a reference image captured from a mask by an inspection apparatus, in accordance with some embodiments of the present disclosure.

FIG. 6 illustrates a schematic view of one stage of a method for performing a mask inspection process on a mask by an inspection apparatus, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “about,” or “substantially” may generally mean within 20 percent, or within 10 percent, or within 5 percent of a given value or range. Numerical quantities given herein are approximate, meaning that the term “around,” “about,” “about,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

During the progression of integrated circuit (IC) development, certain apparatuses are employed to inspect the mask after exposing the wafer. The inspection process for the mask begins with collecting a reference (or golden) image from the mask in an inspection apparatus. This is followed by an exposure on the mask and a subsequent mask inspection. If the mask inspection fails, due to scanning issues, the mask's recipe performing in the inspection apparatus is inhibited. The mask's recipe is then adjusted, which necessitates a recovery time of over 3 hours for the inspection apparatus. Once the tool is ready, the reference image is recollected from the mask by the inspection apparatus. However, scanning issues during the inspection process can lead to recipe modifications that require significant downtime for tool recovery, making the process potentially time-consuming and inefficient.

Therefore, the present disclosure provides a method introduced an inline pre-warning system. This system can ensure inspection apparatus reliability performance by confirming its status before the mask inspection begins. The method can minimize the impact on tool availability during scan fails by ensuring a pre-checking procedure is conducted before the commencement of the mask inspection. This can serve to mitigate the risks associated with scan fails, such as production line stops and the extensive time consumed in failure recovery. Specifically, the system can check multiple parameters, ranging from mask leveling to laser health, ensuring tool readiness. If these checks flag concerns, an auto-recovery step will be implemented before resuming the inspection process on the mask. The auto-recovery step can include compensation mechanisms adjusting for fluctuations in the inspection apparatus, including mask leveling to laser health, to ensure consistent quality on the inspection process.

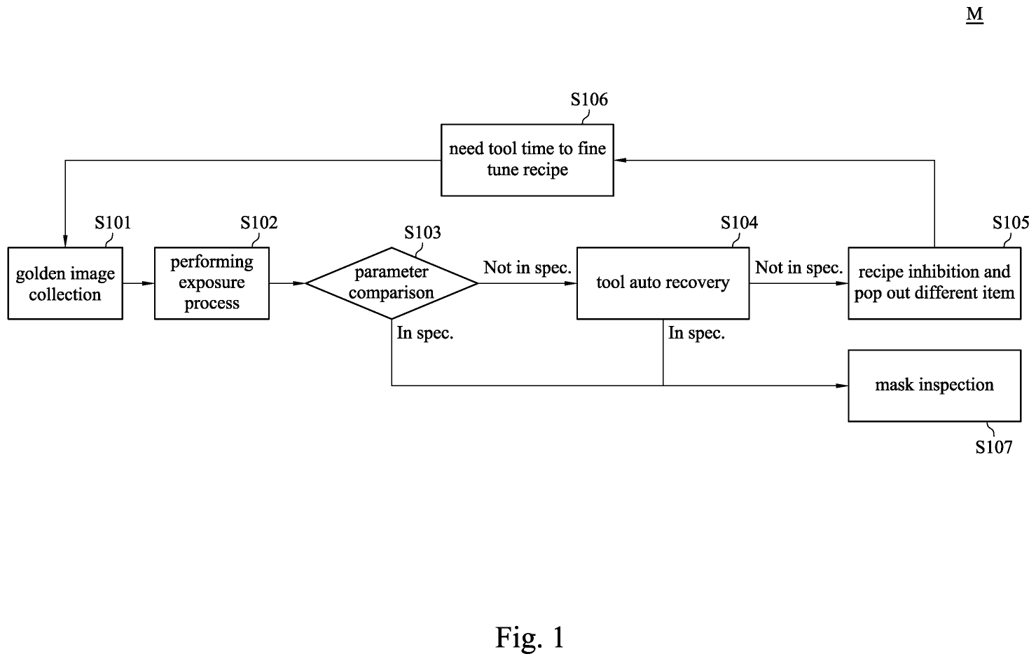

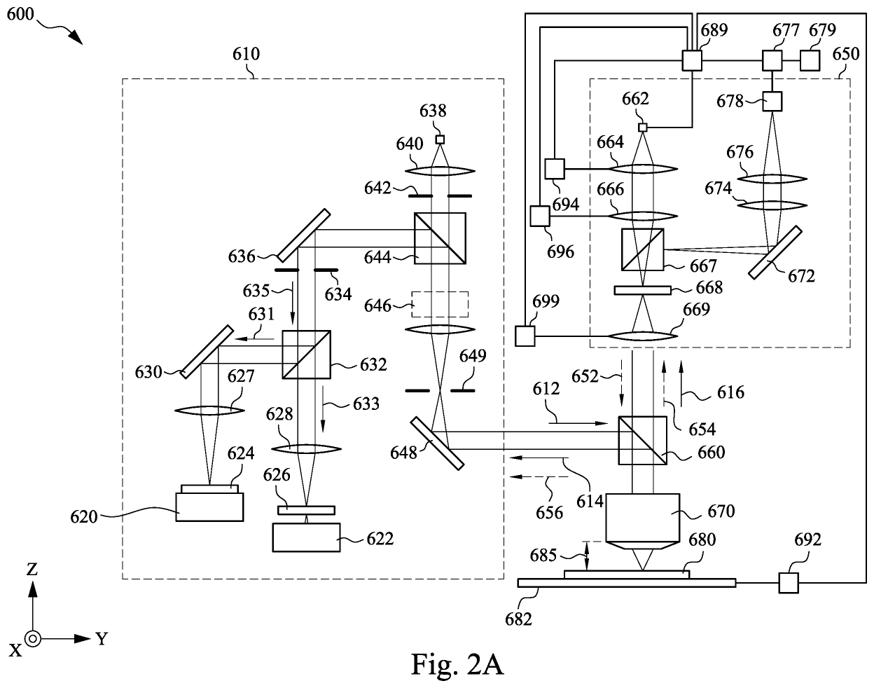

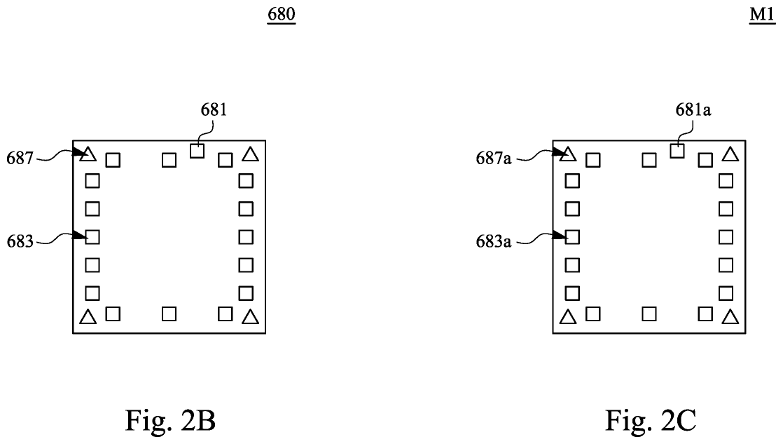

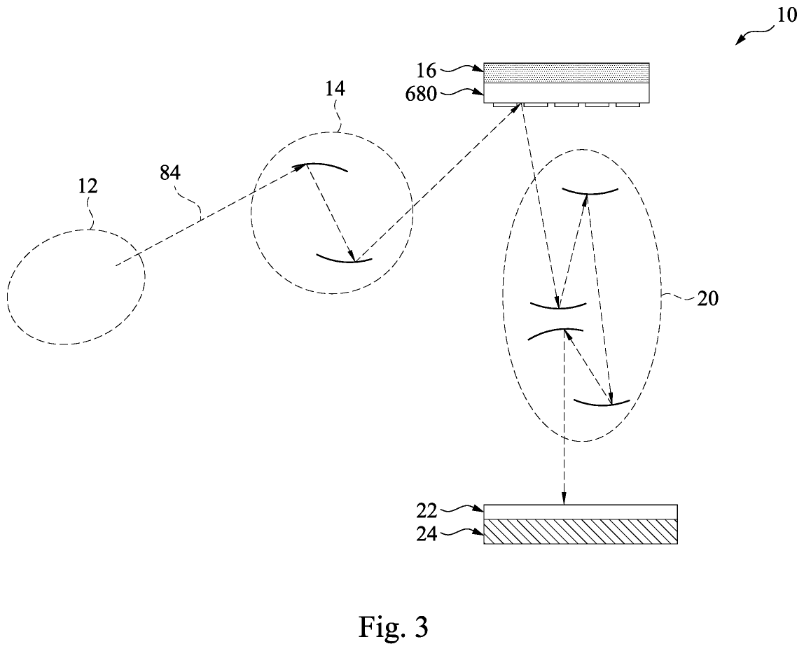

Reference is made to FIG. 1. FIG. 1 illustrates a flow chart of a method M including operations of a mask 680, in accordance with some embodiments of the present disclosure. The method M includes a relevant part of the semiconductor manufacturing process. It is understood that additional operations may be provided before, during, and after the operations shown by FIG. 1, and some of the operations described below can be replaced or eliminated for additional embodiments of the method. The order of the operations/processes may be interchangeable. FIGS. 2A-6 illustrates schematic views of various stages of the method M, in accordance with some embodiments of the present disclosure.

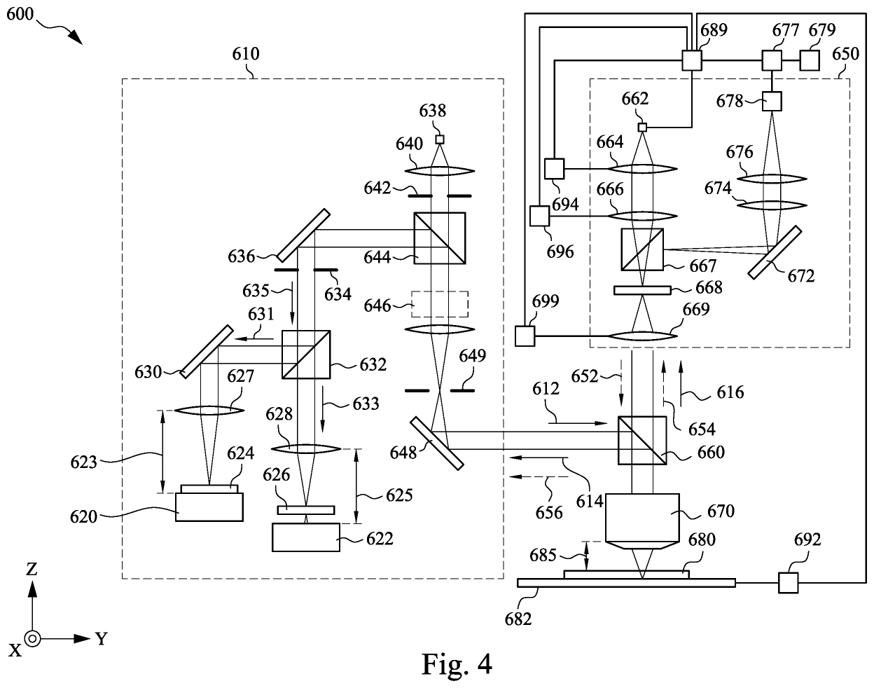

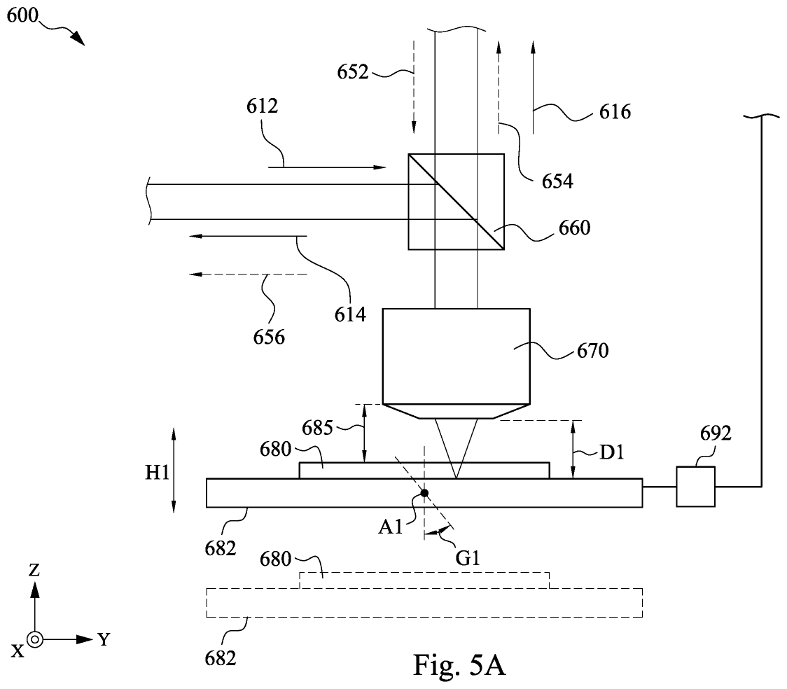

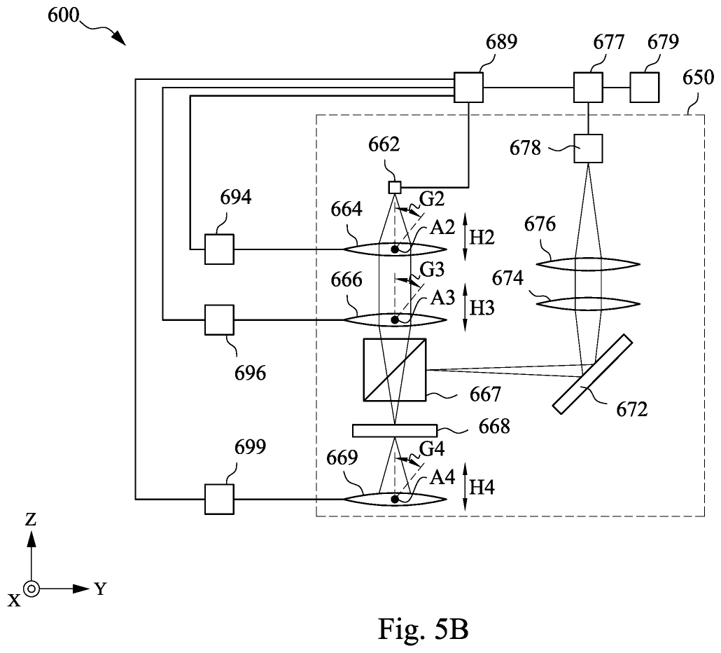

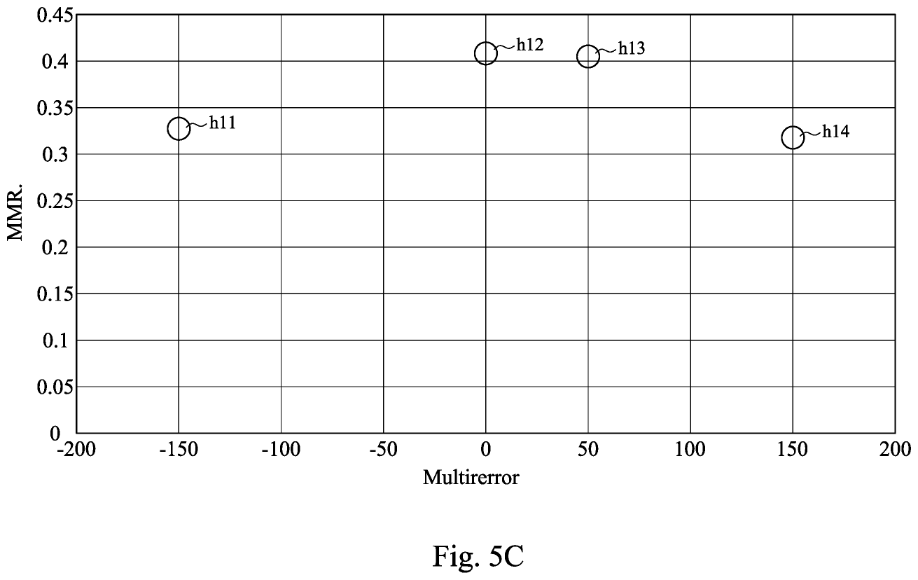

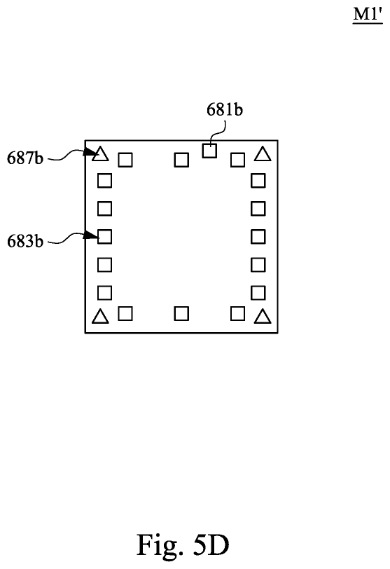

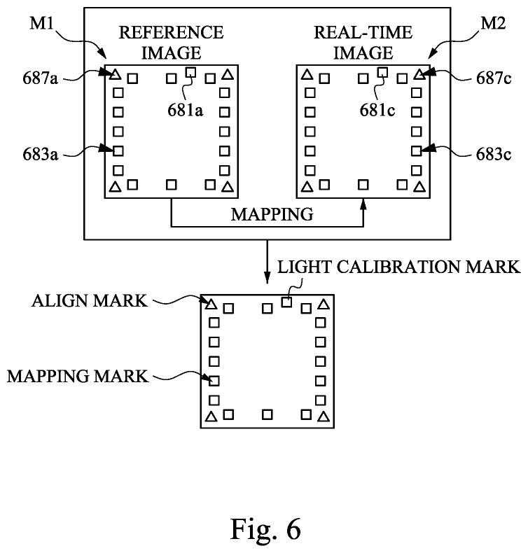

FIG. 2A illustrates a schematic view of one stage of a method for capturing an image of the mask 680 in an inspection apparatus prior to performing an exposure process on the mask 680, in accordance with some embodiments of the present disclosure. FIG. 2B illustrates a schematic view of the mask 680 in accordance with some embodiments of the present disclosure. FIG. 2C illustrates a schematic view of a reference image captured from the mask 680 by an inspection apparatus, in accordance with some embodiments of the present disclosure. FIG. 3 illustrates a schematic view of one stage of a method for operating the mask 680 in a lithography exposure system, in accordance with some embodiments of the present disclosure. FIG. 4 illustrates a schematic view of one stage of a method for operating a parameter comparison in an inspection apparatus based on the mask 680 after performing an exposure process on the mask 680, in accordance with some embodiments of the present disclosure. FIGS. 5A and 5B illustrate schematic views of one stage of a method for performing compensations on an inspection apparatus based on the mask 680, in accordance with some embodiments of the present disclosure. FIG. 5C shows a multi-error versus mask to mask reflection (MMR) plot of an inspection apparatus based on the mask 680, in accordance with some embodiments of the present disclosure. FIG. 5D illustrates a schematic view of a reference image captured from a mask by the inspection apparatus 600, in accordance with some embodiments of the present disclosure. FIG. 6 illustrates a schematic view of one stage of a method for performing the mask 680 inspection process on the mask 680 by an inspection apparatus, in accordance with some embodiments of the present disclosure.

The pre-check procedure for the inspection apparatus 600 can initiate with capturing reflected light intensity on the mask 680 (see blocks 101). Subsequently, a reflected light intensity comparison for the mask 680 is executed (see blocks 103). If the comparison result is accepted, proceeds with the mask inspection on the mask 680 (see blocks 107). If the comparison result is not accepted, the automatic inspection apparatus recovery mechanism can be activated (see blocks 104). Subsequently, a further parameter comparison can be performed. If the inspection apparatus 600 is ready, the mask inspection on the mask 680 can be resumed (see blocks 107). If discrepancies persist on the inspection apparatus 600, the inspection apparatus's recipe can inhibited (see blocks 105), refined (see blocks 106), and rechecked, conducting in another round of reference image acquisition (see blocks 101). Therefore, the pre-check procedure can be used in observing and hypothesizing correlations between the auto-focus level searching and brightness during the mask inspection, validated through cycling tests, facilitating corrections in any disparities in brightness and focus levels. In some embodiments, the mask 680 can be also interchangeably referred to as a substrate or a reticle, and the inspection apparatus 600 can be also interchangeably referred to as an inspection tool or a methodology tool.

Referring back to FIG. 1, the method M then proceeds to block S101 where a reference (or golden) image of a mask is captured by an inspection apparatus. With reference to FIGS. 2A-2C, in some embodiments of block S101, the reference image M1 (see FIG. 2C) is captured by the inspection apparatus 600 (see FIG. 2A) before the block S102. For illustration, acquiring the reference image M1 is performed before the block S102. The timing of acquiring the reference image M1 is given for illustrative purposes. Various timing of acquiring the reference image M1 is within the contemplated scope of the present disclosure. The inspection apparatus 600 (e.g., metrology apparatus) can be configured to provide focusing and provide optical measurement of, for example, CD, overlay, etc.

As shown in FIGS. 2A-2C, the mask 680 (see FIGS. 2A and 2B) can include align marks 687, mapping marks 683, and light calibration mark 681. In some embodiments, the reference image M1 (see FIG. 2C) is acquired by capturing the mapping marks 683 as separate mapping mark images 683a (see FIG. 2C) respectively, and then combining the separate mapping mark images 683a to build the reference image M1. The reference image M1 also includes images of the patterns on the mask 680, align mark images 687a, and light calibration mark image 681a. Each one of the separate images includes the image of at least one of the mapping mark images 683a, and each mapping marks 683 is captured for at least one time. For example, when the mask 680 includes 16 mapping marks 683, the lithography process system 100 captures 16 separate images in which each includes one mapping mark image 683a. Subsequently, the 16 separate images are tailored to build the reference image M1 of the mask.

In some embodiments, the reference image M1 (see FIG. 2C) is acquired when the mask 680 (see FIGS. 2A and 2B) is clean and is not destructed in any part of patterns on the mask. Alternatively stated, when the reference image M1 is acquired, the mask is free of defects. Therefore, in some embodiments, the reference image M1 represents an image of mask in a flawless condition. The reference image M1 is also referred to as “Golden image” in some embodiments. In some embodiments, the analyzer 677 (see FIG. 2A) of the inspection apparatus 600 can decode the separate images as data. The data is stored in the reference image database 679 (see FIG. 2A). In some embodiments, the analyzer 677 of the inspection apparatus 600 can re-decode the data as the separate images. After the data stored in the reference image database 679 is re-decoded as separate images, the analyzer 677 is configured to build the reference image M1 based on the separate images.

The reflected light intensity (e.g., gray-scale) on the light calibration mark 681 (see FIG. 2B) can be used as a basis for detecting the reflected light intensity (e.g., gray scale) of other positions on the mask 680. In some embodiments, the reflected light intensity (e.g., gray scale) on the light calibration mark 681 can used to compare the difference between the real-time image M2 (see FIG. 6) of the mask 680 and the reference image M1 (see FIG. 6) of the mask 680. Furthermore, there are reflection areas with different heights on the light calibration mark 681. When detecting the reflected light intensity, these reflection areas with different heights in the light calibration mark 681 can be used as benchmark for reflection areas with corresponding heights on the mask 680. The light calibration mark 681 can be positioned on the mask 680 to facilitate precise and efficient measurements. In some embodiments, the light calibration mark 681 can be positioned at an edge of the mask 680, making it easily identifiable. In some embodiments, the light calibration mark 681 is positioned proximate to the align mark and at the corner of the mask 680. In some embodiments, the light calibration mark 681 is positioned between the mapping marks. The use of the light calibration mark 681 to measure the reflected light intensity of the mask 680 can allow the inspection process to become quicker and more streamlined than to measure the entire mask 680. The light calibration mark 681 can provide a standardized point of reference, which in turn ensures that measurements are consistently taken from the same point, reducing variability and increasing accuracy.

The light calibration mark 681 (see FIG. 2B) on the mask 680 can vary in quantity based on the specific design and application requirements. In some embodiments, there is only a single light calibration mark 681. In some embodiments, there may be multiple light calibration marks 681 distributed on the mask 680. When there are multiple light calibration marks 681, the reflected light intensity from each light calibration marks 681 can be measured separately. After obtaining the individual intensities, an average value can be calculated to represent the overall reflected light intensity of the mask 680. This average provides a more comprehensive insight into the reflective properties of the mask 680, factoring in potential variations across different regions of the mask 680. When there are multiple light calibration marks 681, the light calibration marks 681 can be placed at the corners and edges of the mask 680. The above number, shape, and arrangement of the light calibration mark 681 are given for illustrative purposes. Various numbers, shapes, and arrangements of the mapping masks and the align marks are within the contemplated scope of the present disclosure.

The formation of an image (e.g., a gray-scale image of the mask 680) based on reflected light intensity can a combination of optics, sensor technology, and image processing. The mask 680 (see FIG. 2A) can be illuminated by a light source (e.g. second input 662 in the inspection apparatus 600). Features on the mask 680 will reflect this light differently based on their properties. Areas on the mask 680 that are highly reflective might correspond to certain features or materials on the mask, while less reflective areas might correspond to others. Subsequently, the reflected light then passes through an optical system in the inspection apparatus 600, which can include lenses and other components, to focus and direct the light towards the detector 678 (see FIG. 2A). Subsequently, the detector 678 can capture the reflected light. Sensors in the detector 678 may include a grid of photodiodes that convert incoming light into an electrical signal. The amount of light hitting each diode varies based on the mask's features and the reflection properties. Subsequently, the electrical signals from the detector 678 can be converted into digital values, creating a digital image. In the case of a gray-scale image, each pixel's value represents a shade of gray, which can be determined by the intensity of the reflected light. The brighter the reflection, the lighter the shade of gray, and vice versa. The gray-scale image can represent different features and regions of the mask 680 in various shades of gray. This image can be analyzed to compare against a reference or to identify defects, deviations, or other characteristics of interest.

As shown in FIG. 2A, the inspection apparatus 600 comprises a focusing module 610, a measurement module 650, a partially reflective optical element 660, an objective 670, and a mask stage 682 configured to hold a mask 680. In some embodiments, the mask stage 682 can be also interchangeably referred to as a mask holder, a substrate stage, or a substrate holder.

The focusing module 610, the partially reflective optical element 660, and the objective 670 are collectively configured to determine whether a target, e.g., on the mask 680 and/or the mask 680 itself, is situated at or near a focal plane of the objective 670, and how to provide relative spatial adjustment between the focal point and the target, e.g., relative spatial adjustment between the focal point and the target (e.g., through movement of the objective 670, and/or through movement of the substrate, etc.). For example, in some embodiments, the relative spatial adjustment makes the working distance 685 equal to, or close to, the focal length of the objective 670 when the target on the mask 680 is determined to be not situated at or near the focal plane of the objective 670.

Specifically, to enable determining whether the target is at or near the focal point, a focusing beam 612 emitted by a first input 638 (e.g., a radiation source such as a lamp or laser, or an input to the focusing module 610 connected or connectable to a radiation source) is directed toward the partially reflective optical element 660 from the focusing module 610 by an optical system comprising a lens 640, an aperture stop 642, a partially reflective optical element 644, and a reflective optical element 648 in the illumination path of the focusing module. The first input 638 is situated at or near the focal plane of the lens 640 so that radiation emitted by the first input 638 can be converted to a collimated beam of radiation as shown in FIG. 2A. The aperture stop 642 is configured to control the amount of the collimated beam of radiation transmitted toward the partially reflective optical element 644, for example, by adjusting the aperture width of the aperture stop 642. The focusing beam 612 is further directed toward the target on the mask 680 by the reflective optical element 648, the partially reflective optical element 660 and the objective 670, and subsequently redirected (e.g., diffracted, reflected, etc.) by the target on, for example, the mask 680.

The redirected focusing beam is collected by the objective 670 and directed back toward the focusing module 610 by, e.g., partially reflective optical element 660. Specifically, at least a portion of the redirected focusing beam 614 (i.e., the beam 635) is directed to a beam splitter 632 by the objective 670, the partially reflective optical element 660, the reflective optical element 648, the partially reflective optical element 644, the reflective optical element 636, and the aperture stop 634 (which is similar to the aperture stop 642), successively in the detection path of the focusing module. The beam splitter 632 divides the beam 635 into a first focusing beam part 631 and a second focusing beam part 633 with desirably substantially equal intensities. The beam splitter 632 further directs the first focusing beam part 631 to a first detection branch, and directs the second focusing beam part 633 to a second detection branch.

In the first detection branch, the first focusing beam part 631 is further directed to a first detector 620 through the use of a first optical system comprising a reflective optical element 630, a lens 627, and a first aperture device 624 placed after the image plane of lens 627 along the beam direction. The first detector 620 is configured to characterize, for example, the intensity of the detected beam of radiation by the first detector 620. The measurement of the detected beam of radiation by the first detector 620 may be further output to a processor (not shown).

In the second detection branch, the second focusing beam part 633 is directed to a second detector 622 through the use of a second optical system comprising a lens 628 and a second aperture device 626 placed before the image plane of lens 628 along the beam direction. The second detector 622 is configured to characterize, for example, the intensity of the detected beam of radiation by the second detector 622. The measurement of the detected beam of radiation by the second detector 622 may be further output to a processor (not shown). In some embodiments, the lens 627 and the first aperture device 624 are substantially similar to the lens 628 and the second aperture device 626, respectively.

In some embodiments, the focusing module 610 uses intensity difference to determine the relative position between the focal point of objective 670 and the target and will be described further herein. However, focusing module 610 may use a different technique to derive the relative position between the focal point and the target, such as phase difference, etc.

The aperture shapes of the first aperture device 624 and the second aperture device 626 can be similar to the aperture shape of the beam of radiation generated by, for example, the first input 638, or of arbitrary shape. However, the aperture sizes of the first aperture device 624 and the second aperture device 626 are appropriately selected and positioned (and calibrated by measuring intensities when, e.g., the target is at the focal plane) to enable focus position determination by, for example, differentiating responses from detectors 620 and 622. This is designed so that it can be determined whether the target is about situated on the focal plane of the objective 670 by comparing the intensities of the beams detected by the first detector 620 and second detector 622. For example, equal intensities measured at both detectors may signify that the target is at or near the focal plane of the objective 670. Unequal intensity between detectors 620 and 622 indicates an out of focus condition, where the direction and amount of focus offset is determined by the difference in signal. Specific defocus values can be determined by calibration.

As a result of the determination made using the information from the first detector 620 and the second detector 622, the processor may instruct one or more actuators to provide focusing by, e.g., shifting the position of the objective 670 in the Z direction, the mask stage 682 in the Z direction, or both. This focusing may be by a specific amount determined by the processor (e.g., a specific value obtained through calibrations). Additionally or alternatively, the intensity of the beam of radiation detected by the first detector 620 and the second detector 622 may be monitored to identify whether the target substantially coincides with the focal point of the objective 670.

The measurement module 650, the partially reflective optical element 660, and the objective 670 are collectively configured to measure the target of the mask 680 to determine, for example, CD, overlay, focus, dose, etc. Specifically, a measurement beam 652 emitted by a second input 662 (e.g., a radiation source such as a lamp or laser, or an input connected or connectable to a radiation source) is directed toward the partially reflective optical element 660 from the measurement module 650 by an optical system comprising lenses 664, 666, a partially reflective optical element 667 and lens 669. The measurement beam 652 is further directed onto the target by the partially reflective optical element 660 and the objective 670, and subsequently radiation from the measurement beam 652 is redirected by the target. At least a portion of the redirected measurement beam 654 is collected by the objective 670 and directed toward the detector 678 (e.g. a CCD or CMOS sensor) via the objective 670, the partially reflective optical element 660, the lens 669, the partially reflective optical element 667, a reflective optical element 672, a lens 674 and a lens 676. The lenses 674 and 676 are arranged in a double sequence of a 4F arrangement. A different lens arrangement can be used, provided that it still provides the radiation of the target onto the detector 678. In some embodiments, the detector 678 is optionally a digital camera that selectively captures video and/or still images within a field of view (FoV) of the detector 678. The detector 678 suitably operates in a visible range of the light spectrum to capture color images, black and white images or gray-scale images and/or may operate in other ranges of the light spectrum, for example, infrared, ultraviolet, etc., to capture images in those respective ranges of the light spectrum. In some embodiments, the detector 678 can be also interchangeably referred to as a scanner device.

The focusing module 610 and the measurement module 650 may operate simultaneously. That is, at a point in time, both the focusing beam 612 and the measurement beam 652 are incident on the mask 680. The relative position between the focal point of the objective 670 and the target on the mask 680 may be automatically adjusted in real-time whenever the mask 680 is not within a specific range of the focal plane of the objective 670.

In addition to the portion of the redirected focusing beam 614, a portion of the redirected measurement beam 656 may be divided from the redirected measurement beam by the partially reflective optical element 660 and be further directed to the focusing module for detection in the first detector 620 and the second detector 622. Additionally or alternatively, a portion of the redirected focusing beam 616 may be divided from the redirected focusing beam by the partially reflective optical element 660 and be further directed to the measurement module for detection in the detector 678. Focusing and measurement beams can employ with different wavelengths and/or non-overlapping spectral bandwidths. Accordingly, one or more notch filters corresponding to the wavelength and/or bandwidth of the measurement beam may be inserted in the focusing module 610 (e.g., between the partially reflective optical element 644 and the reflective optical element 636) to block the portion of the redirected measurement beam 656. Similarly, one or more notch filters corresponding to the wavelength and/or bandwidth of the focusing beam may be inserted in the measurement module 650 (e.g., between the partially reflective optical element 667 and the reflective optical element 672) to block the portion of the redirected focusing beam 616.

In some embodiments, the focusing beam is provided with an intensity distribution such that the radiation is off-axis (e.g., annular, dipole, quadrupole, etc.), while the measurement beam is provided with an intensity distribution that is on-axis (e.g., circular) such that all, or a majority, of the focusing beam is spatially outward of the measurement beam radiation at least at the target/substrate and/or an aperture device. In some embodiments, the measurement beam is provided with an intensity distribution such that the radiation is off-axis (e.g., annular, dipole, quadrupole, etc.), while the focusing beam is provided with an intensity distribution that is on-axis (e.g., circular) such that all, or a majority, of the measurement beam is spatially outward of the focusing beam radiation at least at the target/substrate and/or an aperture device.

Referring back to FIG. 2A, in some embodiments, the first input 638 and/or the second input 662 may provide the radiation with the desired intensity distribution. Additionally or alternatively, a beam shaping optical element (e.g., a diffractive optical element, an axicon (pair), a spatial light modulator, a wedge pyramid, etc.) can be provided in the path of the measurement beam and/or the focusing beam to redirect the radiation to provide the desired intensity distribution. Additionally or alternatively, an aperture device (e.g., a plate with an opening, a spatial light modulator to effectively provide an opening by blocking/reflecting unwanted radiation out of the optical path, a liquid crystal element to block/reflect unwanted radiation out of the optical path, etc.) may be provided in the path of the measurement beam and/or the focusing beam to provide an aperture that defines a desired spatial intensity distribution. Similarly, in some embodiments, a beam shaping optical element and/or an aperture device can be provided to prevent the portion of the redirected measurement beam 656 from reaching the detectors 620, 622 in the focusing module 610. Similarly, additionally or alternatively, the portion of the redirected focusing beam 616 may be prevented from reaching the detector 678 in the measurement module 650 using a beam shaping optical element and/or an aperture device. Further, it will be appreciated different combinations of the devices may be used to arrive at the desired intensity distribution and/or prevent radiation from reaching detectors. For example, a beam shaping optical element may provide the desired intensity distribution while an aperture device may prevent radiation from reaching the detectors.

As mentioned above, in some embodiments, an aperture device is provided to create a desired intensity distribution (also referred to as illumination shape). The aperture device for the focusing beam may be the input 638 (e.g., a fiber), an aperture device provided in a field plane (e.g., at input 638) or aperture device 642 (e.g., in the form of an angular shaping device). The aperture device for the measurement beam may be aperture device 668. The aperture device may be a plate with one or more openings defining the illumination shape(s). For example, the aperture plate may comprise a plurality of openings, each opening defining a different illumination shape and the plate being movable (e.g., rotatable) so that the different openings can be placed in the applicable beam path. In some embodiments, a plurality of aperture plates may be provided and placed into and out of the path of the applicable radiation. Other forms of the aperture device may include a spatial light modulator to effectively provide an illumination opening by blocking/reflecting unwanted radiation out of the optical path, a liquid crystal element to block/reflect unwanted radiation out of the optical path, etc.

In some embodiments, a beam shaping element is provided in the optical path of the focusing beam and/or the measurement beam. In some embodiments, the beam shaping element is effectively configured to convert radiation from one intensity distribution to a different desired intensity distribution such as, for example, convert an on-axis illumination shape to an off-axis illumination shape (or vice versa) (e.g., for creating a desired illumination shape for the focusing and/or measurement beam) or to reverse the shape of radiation such that off-axis radiation is put on-axis and on-axis radiation is put off-axis (or vice versa) (e.g., for preventing radiation from reaching a detector when used in combination with, e.g., an aperture device). In some embodiments, the beam shaping element is positioned in the optical path so that it further can convert any off-axis radiation to on-axis radiation and convert any on-axis radiation to off-axis radiation (or vice versa) when radiation passes the beam shaping element in the reverse direction. Where the beam shaping element does not provide conversion of the illumination intensity distribution in the reverse direction, the beam shaping element would typically be located between input 662 and element 667 for the measurement beam and/or between input 638 and element 644 for the focusing beam. Where the beam shaping element provides conversion of the radiation intensity distribution in the reverse direction, the beam shaping element would typically be located in the optical path between detector 678 and the element 660 for the measurement beam and/or in the optical path between aperture devices 624, 626 and the element 660 (such as beam shaping element 646) for the focusing beam. In some embodiments, the beam shaping element is located at or near a pupil plane, or an optically conjugate plane thereof.

In some embodiments, a beam shaping element 646 is provided in the optical path between the element 660 and the element 644. Thus, the beam shaping element 646 is, in this embodiment, both in the path of supply of radiation to the mask 680 and the path of the return of radiation from mask 680 toward detectors 620, 622. In some embodiments, the beam shaping element 646 is between the partially reflective optical element 644 and the reflective optical element 648. Further, for this embodiment, the focusing beam 612 will have an off-axis illumination shape, while the measurement beam 652 has an on-axis shape. As will be appreciated, the configuration could be reversed. So, in this embodiment, the radiation from input 638 to the beam shaping element 646 has an on-axis shape (e.g., a circular shape provided directly by the input 638 or provided by, e.g., an aperture device between the input 638 and the element 646). The beam shaping element 646 then redirects that radiation to form an off-axis shape (e.g., a ring shape or a multipole arrangement). Therefore, the focusing beam 612 has an off-axis illumination shape for the mask 680. Further, as discussed above, the measurement beam 652 has an on-axis illumination shape.

After the focusing beam 612 and the measurement beam 652 being incident on the mask 680, the portion of the redirected focusing beam 614 and the portion of the redirected measurement beam 656 may collectively form a spatially separated illumination shape. In addition, both the portion of redirected focusing beam 614 and the portion of the redirected measurement beam 656 are directed to the focusing module 610, where the beam shaping element 646 converts the off-axis illumination shape of the portion of the redirected focusing beam 614 to an on-axis illumination shape, and converts the on-axis illumination shape of the portion of the redirected measurement beam 656 to an off-axis illumination shape. Further, the portion of the redirected focusing beam 616 and the portion of the redirected measurement beam 654 may collectively form a same spatially separated illumination shape as discussed above. Both the portion of the redirected focusing beam 616 and the portion of the redirected measurement beam 654 are directed to the measurement module 650.

Referring back to FIG. 1, the method M then proceeds to block S102 where an exposure process is performed by a lithography exposure system using the mask. With reference to FIG. 3, in some embodiments of block S102, the lithography exposure system 10 can be an extreme ultraviolet (EUV) lithography system designed to expose a resist layer by EUV radiation (also interchangeably referred to herein as EUV radiation). The lithography exposure system 10 may include a light source 12, an illuminator 14, a mask stage 16, a projection optics module (or projection optics box (POB)) 20 and a substrate stage 24, in accordance with some embodiments. The elements of the lithography exposure system 10 can be added to or omitted, and the disclosure should not be limited by the embodiment.

The light source 12 is configured to generate radians having a wavelength ranging between about 1 nm and about 100 nm in certain embodiments. In one particular example, the light source 12 generates an EUV radiation with a wavelength centered at about 13.5 nm. Accordingly, the light source 12 is also referred to as an EUV radiation source. However, it should be appreciated that the light source 12 should not be limited to emitting EUV radiation. The light source 12 can be utilized to perform any high-intensity photon emission from excited target fuel.

In various embodiments, the illuminator 14 includes various refractive optic components, such as a single lens or a lens system having multiple lenses (zone plates) or alternatively reflective optics (for EUV lithography exposure system), such as a single mirror or a mirror system having multiple mirrors in order to direct light from the light source 12 onto the mask stage 16, particularly to the mask 680 secured on the mask stage 16. In the present embodiment where the light source 12 generates light in the EUV wavelength range, reflective optics is employed.

The mask stage 16 is configured to secure the mask 680. In some embodiments, the mask stage 16 includes an electrostatic chuck (e-chuck) to secure the mask 680. This is because the gas molecules absorb EUV radiation and the lithography exposure system for the EUV lithography patterning is maintained in a vacuum environment to avoid EUV intensity loss. In the present disclosure, the terms mask, photomask, and reticle are used interchangeably. In some present embodiment, the mask 680 is a reflective mask. One exemplary structure of the mask 680 includes a substrate with a suitable material, such as a low thermal expansion material (LTEM) or fused quartz. In various examples, the LTEM includes TiO₂ doped SiO₂, or other suitable materials with low thermal expansion. The mask 680 includes reflective multilayer deposited on the substrate.

The reflective multilayer includes a plurality of film pairs, such as molybdenum-silicon (Mo/Si) film pairs (e.g., a layer of molybdenum above or below a layer of silicon in each film pair). Alternatively, the reflective multilayer may include molybdenum-beryllium (Mo/Be) film pairs, or other suitable materials that are configurable to highly reflect the EUV radiation. The mask 680 may further include a capping layer, such as ruthenium (Ru), disposed on the reflective multilayer for protection. The mask 680 further includes an absorption layer, such as a tantalum boron nitride (TaBN) layer, deposited over the reflective multilayer. The absorption layer is patterned to define a layer of an integrated circuit (IC). Alternatively, another reflective layer may be deposited over the reflective multilayer and is patterned to define a layer of an integrated circuit, thereby forming an EUV phase shift mask.

The projection optics module (or projection optics box (POB)) 20 is configured for imaging the pattern of the mask 680 on to a semiconductor wafer 22 secured on the substrate stage 24 of the lithography exposure system 10. In some embodiments, the POB 20 has refractive optics (such as for a UV lithography exposure system) or alternatively reflective optics (such as for an EUV lithography exposure system) in various embodiments. The light directed from the mask 680, carrying the image of the pattern defined on the mask, is collected by the POB 20. The illuminator 14 and the POB 20 are collectively referred to as an optical module of the lithography exposure system 10.

In some embodiment, the semiconductor wafer 22 may be made of silicon or other semiconductor materials. Alternatively or additionally, the semiconductor wafer 22 may include other elementary semiconductor materials such as germanium (Ge). In some embodiments, the semiconductor wafer 22 is made of a compound semiconductor such as silicon carbide (SiC), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22 may be a silicon-on-insulator (SOI) or a germanium-on-insulator (GOI) substrate.

In addition, the semiconductor wafer 22 may have various device elements. Examples of device elements that are formed in the semiconductor wafer 22 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, the semiconductor wafer 22 is coated with a resist layer sensitive to the EUV radiation in the present embodiment. Various components including those described above are integrated together and are operable to perform lithography processes.

Following block S102 is block S103 and block S104 designed to optimize the mask inspection process after an exposure process is performed on the mask. The block S103 is associated about a parameter comparison before the commencement of the mask inspection. It is to ensure that the inspection apparatus 600 is in optimal condition. The block S104 is associated about an automatic inspection apparatus recovery and compensation. If discrepancies arise during the parameter comparison, the block S104 can implement an automatic inspection apparatus recovery mechanism. The inspection apparatus 600 can be compensated based on the mask 680. This recovery not only ensures seamless operations but also mitigates potential tool downtime and enhances the reliability of subsequent mask inspections. The compensation can include a parameter comparison of the inspection apparatus 600, and the parameter comparison is conducted based on the mask 680. Parameters evaluated to confirm tool readiness can be associated about mask leveling, focus stability, laser health, and stage control stability.

Therefore, the pre-check procedure can ensure mask inspection quality, and thus high stability and reproducibility on the mask inspection can be implemented, when contrasting reference (or golden) images with real time images. The inspection apparatus 600 can dynamically compensate for inspection apparatus inconsistencies, such as focus offsets, which in turn allows for preventing prolonged production halts and offering time savings when inspection scans fails.

Referring back to FIG. 1, the method M then proceeds to block S103 where a parameter comparison of an inspection apparatus is operated based on a mask after performing an exposure process on the mask. With reference to FIG. 4, in some embodiments of block S103, after the inspection apparatus 600 has undergone multiple inspection processes, at least one inspection parameters of the inspection apparatus may experience an offset. The inspection parameters evaluated to confirm tool readiness can be associated about mask leveling, focus stability, laser health, and stage control stability. In some embodiments, the inspection process can be also interchangeably referred to as a measurement process, and the inspection parameter can be also interchangeably referred to as a measurement parameter. In the case of block S103, the parameter comparison can be done right after the exposure process on the mask, making it an immediate and direct part of the mask inspection workflow. In addition, in the case of block S103, by comparing the parameters of the inspection apparatus 600 based on the mask 680 after the exposure process, potential discrepancies or misalignments can be detected early. This early detection can prevent inaccuracies during the mask inspection, ensuring the quality and reliability of the mask 680. Therefore, the inspection apparatus 600 including the block S103 can serve as an apparatus equipped with an inline pre-warning system.

In some embodiments, the inspection parameters can include the position of the mask stage 682 in the inspection apparatus 600, the position of the lens (e.g., lens 664, 666, 669), and the intensity of the second input 662. Specifically, for the same mask 680, the inspection parameters used to obtain the reference image M1 (see FIGS. 2C and 6) might differ from the inspection parameters used to obtain the real-time image M2 (see FIG. 6). This could result in the reflected light intensity captured by detector 678 at the light calibration mark 681 (see FIG. 2B) of the mask 680 during obtaining reference image M1 being different from the reflected light intensity captured during obtaining the real-time image M2. After obtaining the real-time image M2 of mask 680 through the inspection apparatus 600, when comparing the real-time image M2 with the reference image M1 to identify differences and thus find defects on the mask 680, some areas of the mask 680 might produce erroneous detection results, misjudging certain locations on the mask as having or not having defects, leading to poor outcomes in subsequent semiconductor fabrication processes. Furthermore, the difference in reflected light intensity between the real-time image M2 and the reference image M1 might be so large that effective comparison becomes unfeasible.

During different procedure in the inspection process, the change in the reflected light intensity at the light calibration mark 681 (see FIG. 2B) of mask 680 may be due to a change in the focal position within the inspection apparatus 600, and/or a change in the intensity of the second input 662. Changes in the focal position could result from an offset in the position of the mask stage 682 or an offset in the position of the lenses (e.g., lens 664, 666, 669). The offset in the position of the mask stage 682 can include vertical movement of the mask stage 682 or rotation of the substrate holder, while the offset in the lens position can include vertical movement, horizontal movement, or rotation of the lens.

Therefore, after the mask 680 completes the exposure process and before the detector 678 captures the real-time image M2 (see FIG. 6) of the mask 680, the inspection apparatus 600 can use the detector 678 to first capture the reflected light intensity at the light calibration mark 681 (see FIG. 2B) of the mask 680. In some embodiments, the reflected light intensity can be represented using gray-scale pixels. Then, the detector 678 can transmit information about this reflected light intensity to the analyzer 677. Subsequently, the analyzer 677 can compare the reflected light intensity (e.g., gray-scale pixels) to reference images M1 (see FIG. 2C) associated with the mask 680 stored in a reference image database 679 at the light calibration mark 681, and thus produce a comparison result. This determines whether the inspection parameters used to capture the real-time image M2 of the mask 680 need to be compensated, thereby reducing the difference in reflected light intensity between the reference image and real-time image in the mask 680. In some embodiments, the analyzer 677 can be an image processor.

If at the light calibration mark 681 (see FIG. 2B), the difference in reflected light intensity is within the preset allowable intensity difference range, then the mask 680 can undergo mask inspection in block S107 without compensating for the inspection parameters. In some embodiments, the aforementioned intensity difference can be 0.5% of the reflected light intensity at the light calibration mark 681 when obtaining the reference image M1 (see FIG. 2C), such as about 0.5, 1, 2, 3, 4, 5, 6, 7, 8, 9, 10, 15, 20, 25, 30, 35, 40, 45, 50%. The block S107 can involve capturing the real-time image M2 (see FIG. 6) of the entire or regions of mask 680. Then, the real-time image M2 is compared with the reference image M1 to determine if there are defects on the mask 680 or to identify the location of defects on the mask 680, to decide whether to conduct a cleaning process to remove defects on the mask 680.

If, at the light calibration mark 681 (see FIG. 2B), the difference in reflected light intensity is outside the preset intensity difference range, then before capturing the real-time image M2 (see FIG. 6) of mask 680, the block S104 for compensating inspection parameters can be conducted, to reduce the difference in reflected light intensity between the reference image and real-time image in the mask 680.

Furthermore, because different masks might use different inspection parameters when capturing their reference images, when capturing real-time images of different masks, the inspection parameters used might differ. This reduces the difference in reflected light intensity between the reference image and real-time image at the light calibration mark 681 (see FIG. 2B) on the same mask 680, facilitating the subsequent inspection of defects on different masks. In some embodiments, the comparison of reflected light intensity uses gray-scale pixels (or grey-level pixel).

Referring back to FIG. 1, the method M then proceeds to block S104 where a compensation is performed on the inspection apparatus based on the mask to automatically recover a status of the inspection apparatus. With reference to FIGS. 5A-5C in some embodiments of block S104, the compensation is performed on the inspection apparatus 600 based on the mask 680 to automatically adjust a status of the inspection apparatus 600. Specifically, if the inspection parameters used by the inspection apparatus 600 for measuring mask 680 (for instance, the position of the mask stage 682, the position of the lens, and the intensity of the light source) need to be compensated to adjust the status of the inspection apparatus, then it further needs to be determined which among multiple inspection parameters should be compensated. Initially, the analyzer 677 (see FIG. 4) can transmit the comparison result to a controller 689 (see FIG. 4). Then, the controller 689 can control the driving elements 692, 694, 696, and/or 699 (see FIG. 4) to trigger or actuate the vertical movement and/or rotation of the mask stage 682 and the lens 664, 666, and/or 669, in order to adjust the inspection parameters. The driving element 692, 694, 696, and/or 699 in the inspection apparatus 600 is a mechanical or electromechanical component designed to induce motion or change the position of specific parts in the inspection apparatus 600. In some embodiments, the driving element 692, 694, 696, and/or 699 can be a stepper motor, a servo motor, a liner actuator, a pneumatic actuator, or a piezoelectric driver. The compensation can be conducted by performing a parameter comparison of the inspection apparatus 600, and the parameter comparison is conducted based on the mask 680.

For example, referring to FIGS. 5A and 5C, when at least one inspection parameters of the inspection apparatus 600 needs to be compensated, the controller 689 (see FIG. 4) can choose to first use the driving element 692 to vertically move the mask stage 682 of the inspection apparatus 600 away from or closer to the partially reflective optical element 660 by a vertical movement H1, changing the distance D1 between the mask stage 682 and the partially reflective optical element 660, while simultaneously fixing other inspection parameters. Then, using the detector 678 (see FIG. 4), the reflected light intensity at the light calibration mark 681 (see FIG. 2B) on the mask 680 under different vertical movements H1 is measured. For instance, FIG. 5C shows the inspection results for the mask stage 682 at four different vertical movements h11, h12, h13, and h14, but this disclosure is not limited thereto. In some embodiments, the number of vertical movements can be at least two, such as 2, 3, 4, 5, 6, 7, 8, 9, or 10.

Subsequently, the detector 678 (see FIG. 4) can transmit the inspection results to the analyzer 677 (see FIG. 4). Subsequently, the analyzer 677 can compare the different reflected light intensities (e.g., gray-scale pixels) to reference image M1 (see FIG. 2C) associated with mask 680 stored in the reference image database 679 at the light calibration mark 681 (see FIG. 2B), producing comparison results. If the analyzer 677 determines that at least one of the differences in reflected light intensities under different vertical movements h11, h12, h13, and h14 is within the preset intensity difference range, the analyzer 677 will decide the vertical movement (e.g., vertical movement h14 shown in FIG. 5C) corresponding to the smallest difference in reflected light intensity. Subsequently, the analyzer 677 can transmit this inspection parameter (i.e., the vertical movement h14 shown in FIG. 5C) to the controller 689. In some embodiments, the vertical movement h14 can be also interchangeably referred to as an adjustment parameter.

Subsequently, the controller 689 can control the driving element 692 to trigger or actuate the mask stage 682 to move by the vertical movement h14 to adjust the distance D1 between the mask stage 682 and the partially reflective optical element 660, thereby proceeding to the subsequent block S107 and reducing the difference in reflected light intensity between the reference image and real-time image on the mask 680. The position of the mask stage 682 can be associated about maintaining focus stability. Consequently, through this multierror offset, a confocal adjustment can be made, enhancing the brightness contrast on the mask 680.

The vertical movement H1 of the mask stage 682 is based on the position of the mask stage 682 in its state without performing any measurement procedures as a reference (e.g., vertical movement h12). In some embodiments, the vertical movement H1 can be divided into an upward vertical movement (e.g., vertical movements h13 and h14) and a downward vertical movement (e.g., vertical movement h11). In some embodiments, the second test's upward vertical movement (e.g., vertical movement h14, about 150 nm) is more than twice (e.g., three times) the first test's upward vertical movement (e.g., vertical movement h13, about 50 nm), and there are no other vertical movements between the first and second upward vertical movements. In some cases, the second test's upward vertical movement can be twice or less than the first test's upward vertical movement. For example, the second test's upward vertical movement can be about 1.2, 1.4, 1.6, 1.8, 2, 2.2, 2.4, 2.6, 2.8, 3, 3.2, 3.4, 3.6, 3.8, or 4 times the first test's upward vertical movement. Similarly, in some embodiments, the second test's downward vertical movement can be about twice, more than twice, or less than twice the first test's downward vertical movement, such as about 1.2, 1.4, 1.6, 1.8, 2, 2.2, 2.4, 2.6, 2.8, 3, 3.2, 3.4, 3.6, 3.8, or 4 times, and there are no other vertical movements between the first and second downward vertical movements. In some embodiments, the first test's upward vertical movement can be between about 10 and 150 nm, such as about 10, 20, 30, 40, 50, 60, 70, 80, 90, 100, 110, 120, 130, 140, or 150 nm, but this disclosure is not limited thereto. In some embodiments, the first test's downward vertical movement can be between about 10 and 150 nm, such as about 10, 20, 30, 40, 50, 60, 70, 80, 90, 100, 110, 120, 130, 140, or 150 nm, but this disclosure is not limited thereto.

If the analyzer 677 determines that the differences in reflected light intensity under different vertical movements h11, h12, h13, and h14 are all outside the preset intensity difference range, then the inspection apparatus 600 can continue to compensate based on at least one other inspection parameters (e.g., rotation of the mask stage 682, vertical movement and/or rotation of the lenses 664, 666, 669) to reduce the reflected light intensity difference between the reference image M1 and real-time image M2 at the light calibration mark 681 (see FIG. 2B) of the mask 680. However, the order of compensating the inspection parameters is not limited by this disclosure. In some embodiments, the inspection apparatus 600 can first adjust lenses 664, 666, 669 or the second input 662 to reduce the reflected light intensity difference between the reference image and real-time image on the mask 680.

As shown in FIG. 5A, the mask stage 682 of the inspection apparatus 600 can rotate by an angle G1 around a horizontal axis A1 to compensate for inspection parameters. Specifically, the controller 689 (see FIG. 4) can use the driving element 692 to rotate the mask stage 682 of the inspection apparatus 600 around a horizontal axis A1 relative to the partially reflective optical element 660 by the angle G1. This can change the orientation between the mask stage 682 and the partially reflective optical element 660 while simultaneously fixing other inspection parameters (or keeping other inspection parameters constant). Subsequently, the detector 678 (see FIG. 4) can measure the intensity of reflected light at the light calibration mark 681 (see FIG. 2B) on the mask 680 under different angles G1. In some embodiments, at least two rotation angles G1, such as 2, 3, 4, 5, 6, 7, 8, 9, or 10, can be tested.

Subsequently, the detector 678 (see FIG. 4) can transmit the inspection results to the analyzer 677 (see FIG. 4). Subsequently, the analyzer 677 can compare the different reflected light intensities (e.g., gray-scale pixels) to the reference image M1 (see FIG. 2C) associated with the mask 680 stored in the reference image database 679 at the light calibration mark 681 (see FIG. 2B) and thus produce comparison results. If the analyzer 677 determines that the differences in reflected light intensity under different rotation angles G1 are within a preset intensity difference range, the analyzer 677 will decide on the rotation angle G1 corresponding to the smallest difference in reflected light intensity. In some embodiments, this corresponding rotation angle G1 can be also interchangeably referred to as an adjustment parameter. Subsequently, the analyzer 677 can transmit this corresponding rotation angle G1 to the controller 689. The controller 689 then can control the driving element 692 to actuate the mask stage 682 to rotate by the corresponding angle G1, adjusting its orientation relative to the partially reflective optical element 660 for the subsequent block S107, thereby reducing the reflected light intensity difference between the reference image M1 and real-time image M2 on the mask 680. The rotation of the mask stage 682 is linked to mask leveling, facilitating stage realignment that subsequently ensures stage control stability.

The rotation angle G1 of the mask stage 682 is based on its position when no measurement procedure is performed. In some embodiments, the rotation angle G1 can be divided into clockwise and counterclockwise rotations. In some embodiments, the second test's clockwise rotation angle can be more than twice the first test's clockwise rotation angle, with no other rotation angles between the first and second clockwise rotations. In some embodiments, the second test's clockwise rotation angle can be twice or less than the first test's clockwise rotation angle. For example, the second test's clockwise rotation angle can be about 1.2, 1.4, 1.6, 1.8, 2, 2.2, 2.4, 2.6, 2.8, 3, 3.2, 3.4, 3.6, 3.8, or 4 times the first test's clockwise rotation. Similarly, in some embodiments, the second test's counterclockwise rotation angle can be about twice, more than twice, or less than twice the first test's counterclockwise rotation angle, such as about 1.2, 1.4, 1.6, 1.8, 2, 2.2, 2.4, 2.6, 2.8, 3, 3.2, 3.4, 3.6, 3.8, or 4 times, and there are no other rotation angles between the first and second counterclockwise rotation angles.

As shown in FIG. 5B, at least one of the lenses 664, 666, 669 of the inspection apparatus 600 can move vertically by a vertical movement of H2, H3, or H4 to compensate for inspection parameters. Specifically, the controller 689 (see FIG. 4) can use the driving elements 694, 696, or 699 to move at least one of the lenses 664, 666, 669 of the inspection apparatus 600 vertically either away from or closer to the second input 662 by a vertical movement H2, H3, or H4. This can change the distance between at least one of the lenses 664, 666, 669 and the second input 662 while simultaneously fixing other inspection parameters (or keeping other inspection parameters constant). Subsequently, the detector 678 (see FIG. 4) can measure the reflected light intensity at the light calibration mark 681 (see FIG. 2B) on the mask 680 under different vertical movements H2, H3, or H4. In some embodiments, the tested vertical movements for at least one of the lenses 664, 666, 669 can be at least two, such as 2, 3, 4, 5, 6, 7, 8, 9, or 10.

Subsequently, the detector 678 (see FIG. 4) can transmit the inspection results to the analyzer 677 (see FIG. 4). Subsequently, the analyzer 677 can compare the different reflected light intensities (e.g., gray-scale pixels) to the reference image M1 (see FIG. 2C) associated with the mask 680 stored in the reference image database 679 at the light calibration mark 681 (see FIG. 2B) and thus produce comparison results. If the analyzer 677 determines that the differences in reflected light intensity under different vertical movements H2, H3, or H4 are within a preset intensity difference range, the analyzer 677 will decide on the vertical movement corresponding to the smallest difference in reflected light intensity, either vertical movement H2, H3, or H4. Subsequently, the analyzer 677 can transmit the corresponding inspection parameter to the controller 689. In some embodiments, this corresponding inspection parameter can be also interchangeably referred to as an adjustment parameter. The controller 689 can control the driving elements 694, 696, or 699 to move the lens 664, 666, or 669 by the determined vertical movement H2, H3, or H4, adjusting the distance between the lens 664, 666, or 669 and the second input 662, for the subsequent block S107, thereby reducing the reflected light intensity difference between the reference image and the real-time image on the mask 680.

The vertical movements H2, H3, or H4 of the lens 664, 666, or 669 are based on the position of the lens 664, 666, or 669 when no measurement procedure is performed. In some embodiments, the vertical movements H2, H3, or H4 can be divided into upward and downward movements. In some embodiments, the second test's upward vertical movement H2, H3, or H4 can be more than twice the first test's upward vertical movement, and there are no other vertical movements between the first and second upward vertical movements. For example, the second test's upward movement can be about 1.2, 1.4, 1.6, 1.8, 2, 2.2, 2.4, 2.6, 2.8, 3, 3.2, 3.4, 3.6, 3.8, or 4 times the first test's upward movement. In some embodiments, the second test's downward vertical movement H2, H3, or H4 can be about twice, more than twice, or less than twice the first test's downward vertical movement, and there are no other vertical movements between the first and second downward movements. For example, the second test's downward movement can be about 1.2, 1.4, 1.6, 1.8, 2, 2.2, 2.4, 2.6, 2.8, 3, 3.2, 3.4, 3.6, 3.8, or 4 times the first test's downward vertical movement.

As shown in FIG. 5B, at least one of the lenses 664, 666, 669 in the inspection apparatus 600 can rotate by an angle G2, G3, or G4 based on the horizontal axis lines A2, A3, or A4 to compensate for inspection parameters. Specifically, the controller 689 (see FIG. 4) can use the driving elements 694, 696, or 699 to rotate at least one of the lenses 664, 666, 669 of the inspection apparatus 600 by an angle G2, G3, or G4 relative to the second input 662 based on the horizontal axis lines A2, A3, or A4. This can change the orientation between at least one of the lenses 664, 666, 669 and the second input 662 while simultaneously fixing other inspection parameters (or keeping other inspection parameters constant). Subsequently, the detector 678 (see FIG. 4) can measure the reflected light intensity of lens 664, 666, or 669 at various angles G2, G3, or G4 on the light calibration mark 681 (see FIG. 2B) of mask 680. In some embodiments, the tested rotation angles of at least one of the lenses 664, 666, 669 can be at least two, such as 2, 3, 4, 5, 6, 7, 8, 9, or 10.

Subsequently, the detector 678 (see FIG. 4) can transmit the inspection results to the analyzer 677 (see FIG. 4). Subsequently, the analyzer 677 can compare the different reflected light intensities (e.g., gray-scale pixels) to the reference image M1 (see FIG. 2C) associated with mask 680 stored in the reference image database 679 at the light calibration mark 681 (see FIG. 2B) and produces comparison results. If the analyzer 677 determines that the differences in reflected light intensity under different rotation angles G2, G3, or G4 are within a preset intensity difference range, the analyzer 677 will decide on the rotation angle corresponding to the smallest difference in reflected light intensity, either rotation angle G2, G3, or G4. Subsequently, the analyzer 677 can transmit this corresponding rotation angle to the controller 689. In some embodiments, this corresponding rotation angle G2, G3, or G4 can be also interchangeably referred to as an adjustment parameter. The controller 689 can control the driving element 694, 696, or 699 to rotate the lens 664, 666, or 669 by the corresponding rotation angle G2, G3, or G4, adjusting the orientation between the lens 664, 666, or 669 and the second input 662, and then proceeds to the subsequent block S107, reducing the reflected light intensity difference between the reference image M1 and the real-time image M2 on the mask 680.

The rotation angles G2, G3, or G4 of the lens 664, 666, or 669 are based on the position of the lens 664, 666, or 669 when no measurement procedure is performed. In some embodiments, the rotation angles G2, G3, or G4 can be divided into clockwise and counterclockwise rotations. In some embodiments, the second test's clockwise rotation angle can be more than twice the first test's clockwise rotation angle, and there are no other rotations between the first and second clockwise rotation angles. In some embodiments, the second test's clockwise rotation angle can be about twice or less than the first test's clockwise rotation angle. For example, the second test's clockwise rotation angle can be about 1.2, 1.4, 1.6, 1.8, 2, 2.2, 2.4, 2.6, 2.8, 3, 3.2, 3.4, 3.6, 3.8, or 4 times the first test's clockwise rotation angle. Similarly, in some embodiments, the second test's counterclockwise rotation angle can be about twice, more than twice, or less than the first test's counterclockwise rotation angle, for example, about 1.2, 1.4, 1.6, 1.8, 2, 2.2, 2.4, 2.6, 2.8, 3, 3.2, 3.4, 3.6, 3.8, or 4 times, and there are no other rotation angles between the first and second counterclockwise rotation angles.

As shown in FIG. 5B, the power of the second input 662 in the inspection apparatus 600 can be increased or decreased by the controller 689 (see FIG. 4) for compensation of inspection parameters while simultaneously fixing other inspection parameters (or keeping other inspection parameters constant). In some embodiments, if the power of the second input 662 increases, it will result in a brighter image, while a decrease of the power of will produce a darker image. In some embodiments, the brightness of the image can be proportional to the power of the second input 662.

Subsequently, the detector 678 (see FIG. 4) can measure the reflected light intensity of the second input 662 under different light intensities at the light calibration mark 681 (see FIG. 2B) on the mask 680. In some embodiments, the number of light intensities tested for the second input 662 can be at least two, such as 2, 3, 4, 5, 6, 7, 8, 9, or 10. Subsequently, the detector 678 (see FIG. 4) can transmit the inspection results to the analyzer 677 (see FIG. 4). Subsequently, the analyzer 677 can compare different reflected light intensities (e.g., gray-scale pixels) to reference image M1 (see FIG. 2C) associated with the mask 680 stored in the reference image database 679 at the light calibration mark 681 and produces comparison results. If the analyzer 677 determines that the differences in reflected light intensity under different powers are within a preset intensity difference range, the analyzer 677 will decide on the power corresponding to the smallest difference in reflected light intensity. In some embodiments, this corresponding power of the second input 662 can be also interchangeably referred to as an adjustment parameter. Subsequently, the analyzer 677 can transmit this corresponding light intensity to the controller 689. Subsequently, the controller 689 can control the second input 662 to the corresponding light intensity, and then proceeds to the subsequent block S107, reducing the reflected light intensity difference between the reference image and the real-time image on mask 680. Adjusting the light intensity of the second input 662 (or laser) can influence the reflected light intensity from the mask 680, enhancing the laser's health. Consequently, this can elevates the brightness of the mask 680.

The tested light intensity of the second input 662 is based on its state as a position reference when no measurement procedure is conducted. In some embodiments, the light intensity of the second test can be more than about twice the light intensity of the first test, with no other light intensities between the first and second tests. In some embodiments, the light intensity of the second test can be about twice or less than the light intensity of the first test. For example, the light intensity of the second test can be about 1.2, 1.4, 1.6, 1.8, 2, 2.2, 2.4, 2.6, 2.8, 3, 3.2, 3.4, 3.6, 3.8, or 4 times the light intensity of the first test.

If, after performing the at least one aforementioned inspection parameters, all differences in reflected light intensity are outside the preset intensity difference range, then block S105 can be proceeded to. The block S105 can involve using the controller 689 to inhibit the measurement recipe related to mask 680 in the inspection apparatus 600 (e.g., the light intensity of the second input 662) and pop out a different item to prevent similar measurement situations on mask 680 due to issues with the apparatus 600 itself. In some embodiments, the measurement recipe can be also interchangeably referred to as an inspection recipe.

Following block S105 is block S106, which may involve adjusting the measurement recipe for the mask 680 (e.g., adjusting the position of the mask stage 682, the position of the lens, and the light intensity). That is, after a series of inspections, if consistent anomalies or deviations are detected, the recipe parameters of the measurement recipe can be adjusted. The measurement recipe can acts as a roadmap for the inspection apparatus 600, ensuring that mask 680 inspections are both consistent and accurate. The flexibility to modify this recipe can ensure the system remains adaptive to evolving requirements and challenges. In some embodiments, the measurement recipe associated with the mask 680 in the inspection apparatus 600 represents a predefined set of inspection parameters and instructions that guide how the mask 680 is to be inspected. This measurement recipe can define various settings and conditions under which the mask (e.g., the mask 680) undergoes inspection to ensure accurate and consistent results. The components of the measurement recipe can include optical settings, focus parameters, scan speed and resolution, reference points, and threshold values. In some embodiments, the optical settings can determine the light intensity, wavelength, and angle of incidence when inspecting the mask 680. The focus parameters can include depth of field and ensuring the mask is in optimal focus for accurate measurement. The scan speed and resolution can determines how quickly the inspection apparatus 600 moves over the mask 680 and at what resolution images or data are captured. The reference points can be related to about specific regions or marks on the mask 680 (e.g., the light calibration mark 681) to be used for calibration or comparison. The threshold values can be predetermined values that can help in identifying defects or variations in the mask 680.

Before the adjustments on the measurement recipe for the mask 680 are made, an inspection can be conducted using the existing measurement recipe. As the mask 680 is inspected using the inspection apparatus 600, data is collected, such as speed of the process, energy consumption, and any discrepancies between expected and actual outcomes. This collected data can be then analyzed to identify patterns or anomalies. Based on the insights from the data analysis, the measurement recipe can be adjusted. These adjustments can include altering inspection durations, modifying optical intensities, or adjusting focal depths. With the adjusted measurement recipe, the mask 680 can be inspected again, and the results are carefully observed. The outcomes from the adjusted measurement recipe can be compared against the benchmarks set during the initial assessment on the mask 680. This comparison can help determine whether the adjustments led to improvements. The feedback loop is iterative. If the adjustments lead to improvements, they are retained, and the adjusted measurement can become the new standard. If not, further adjustment might be necessary, triggering another cycle of the feedback loop.

After the block S106 is the block S101, which may involve capturing a new reference image M1′ (see FIG. 5D) for the mask 680 in the inspection apparatus 600 using the adjusted recipe, and storing this reference image M1′ in the reference image database 679 to replace the reference image M1. In some embodiments, the inspection recipe can be also interchangeably referred to as a measurement recipe. The reference image M1′ also includes images of the patterns on the mask 680, align mark images 687b, mapping mark images 683b, and light calibration mark image 681b.

Referring back to FIG. 1, the method M then proceeds to block S107 where a mask inspection is performed on the mask after compensation of the inspection apparatus based on the mask. With reference to FIG. 6, in some embodiments of block S107, the real-time image M2 of the mask 680 can be inspected. The detector 678 is configured to inspect the real-time image M2 of the mask 680 being mapped in order to determine whether the mask 680 is defective. In some embodiments, when the mask 680 has contaminated particles on the patterns of the mask 860, the real-time image M2 is different from the reference image M1 because images of the contaminated particles are formed in the real-time image M2. In some embodiments, when the patterns of the mask 680 are destructed, the real-time image M2 is different from the reference image M1 because images of the destructed patterns are formed in the real-time image M2. Alternatively stated, when the real-time image M2 is different from the reference image M1, the detector 678 determines that the mask is defective. The above defective situations are given for illustrative purposes. Various defective situations are within the contemplated scope of the present disclosure. Specifically, the detector 678 is configured to capture the real-time image M2 of the mask 680. The real-time image M2 of the mask 680 is captured by reflecting the source light at the mask 680 to generate the real-time image M2 which includes images of the patterns and every mapping marks (e.g., align mark images 687c, mapping mark images 683c, and light calibration mark image 681c). Subsequently, the real-time image M2 is mapped with the reference image M1.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method introduced an inline pre-warning system. This system can ensure inspection apparatus reliability performance by confirming its status before the mask inspection begins. The method can minimize the impact on tool availability during scan fails by ensuring a pre-checking procedure is conducted before the commencement of the mask inspection. This can serve to mitigate the risks associated with scan fails, such as production line stops and the extensive time consumed in failure recovery. Specifically, the system can check multiple parameters, ranging from mask leveling to laser health, ensuring tool readiness. If these checks flag concerns, an auto-recovery step will be implemented before resuming the inspection process on the mask. The auto-recovery step can include compensation mechanisms adjusting for fluctuations in the inspection apparatus, including mask leveling to laser health, to ensure consistent quality on the inspection process.

In some embodiments, a method includes capturing a first reference image of a mask by an inspection apparatus, the capturing comprising measuring a first reflected light intensity from the first reference image; performing, using the mask, an exposure process on a wafer; after performing the exposure process, measuring a second reflected light intensity on the mask by the inspection apparatus; comparing the second reflected light intensity with the first reflected light intensity from the first reference image; determining whether a first comparison result of the first and second reflected light intensities is acceptable; in response to the determination determines that the first comparison result is unacceptable, adjusting an inspection parameter of the inspection apparatus. In some embodiments, the method further includes in response to the determination determines that the first comparison result is acceptable, performing an inspection process on the mask by the inspection apparatus. In some embodiments, the inspection parameter comprises a vertical position of a mask stage in the inspection apparatus relative to an optical element in the inspection apparatus. In some embodiments, the inspection parameter comprises a leveling status of a mask stage in the inspection apparatus. In some embodiments, the inspection parameter comprises a power of a light source in the inspection apparatus. In some embodiments, the method further includes after adjusting the inspection parameter, measuring a third reflected light intensity on the mask by the inspection apparatus. In some embodiments, the method further includes comparing the first and third reflected light intensities; determining whether a second comparison result of the first and third reflected light intensities is acceptable. In some embodiments, the method further includes in response to the determination determines that the second comparison result is acceptable, performing an inspection process on the mask by the inspection apparatus. In some embodiments, the method further includes in response to the determination determines that the second comparison result is unacceptable, inhibit an inspection recipe of the mask used in the inspection apparatus. In some embodiments, the method further includes in response to the determination determines that the second comparison result is unacceptable, adjusting an inspection recipe of the mask used in the inspection apparatus. In some embodiments, the method further includes capturing a second reference image of the mask by the inspection apparatus using the adjusted inspection recipe.

In some embodiments, a method includes measuring a first reflected light intensity of a light calibration mark on a mask by an inspection apparatus; after measuring the first reflected light intensity, guiding a light in an exposure system using the mask; after guiding the light in the exposure system, measuring a second reflected light intensity of the light calibration mark on the mask by the inspection apparatus, wherein the mask is supported by a mask stage in a first position as an inspection parameter; determining whether a first reflection difference between the first and second reflected light intensities is acceptable; in response to the determination determines that the first reflection difference is acceptable, performing an inspection process on the mask by the inspection apparatus. In some embodiments, the method further includes in response to the determination determines that the first reflection difference is unacceptable, measuring a plurality of third reflected light intensities of the light calibration mark on the mask by the inspection apparatus with the mask stage in a plurality of second positions different than the first position for measuring the second reflected light intensity. In some embodiments, the method further includes calculating a plurality of second reflection differences between each of the third reflected light intensities and the first reflected light intensity. In some embodiments, the method further includes determining a smallest one of the second reflection differences; compensating the first position of the mask stage with the smallest one of the second reflection differences. In some embodiments, the method further includes determining whether the second reflection differences are acceptable; in response to the determination determines that the second reflection differences are unacceptable, adjusting an inspection recipe of the mask used in the inspection apparatus.

In some embodiments, a system includes a mask stage in an inspection apparatus, a light source, a reflective optical element, a controller, a detector, an analyzer, and a first driving element. The light source is over the mask stage. The reflective optical element is between the light source and the mask stage. The controller initiates a first relative motion between the mask stage and the reflective optical element. The detector is disposed in the inspection apparatus, wherein the detector is configured to capture reflected light intensity on a mark over the mask stage. The analyzer is electrically connected to the detector, wherein the analyzer is configured to generate an adjustment parameter to the controller based on the captured reflected light intensity. The first driving element is connected to the mask stage, wherein the first driving element is configured to adjust a position of the mask stage in response to the adjustment parameter. In some embodiments, the first relative motion initiated by the controller includes moving the mask stage vertically. In some embodiments, the controller initiates a power variation on the light source, the power variation allowing a variation of the reflected light intensity on the mark. In some embodiments, the system further includes a lens in the inspection apparatus and a second driving element connected to the lens, wherein the controller initiates a second relative motion between the lens and the light source through the second driving element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
capturing a first reference image of a mask by an inspection apparatus, the capturing comprising measuring a first reflected light intensity from the first reference image;
performing, using the mask, an exposure process on a wafer;
after performing the exposure process, measuring a second reflected light intensity on the mask by the inspection apparatus;
comparing the second reflected light intensity with the first reflected light intensity from the first reference image;
determining whether a first comparison result of the first and second reflected light intensities is acceptable; and
in response to the determination determines that the first comparison result is unacceptable, adjusting an inspection parameter of the inspection apparatus.

2. The method of claim 1, further comprising:
in response to the determination determines that the first comparison result is acceptable, performing an inspection process on the mask by the inspection apparatus.

3. The method of claim 1, wherein the inspection parameter comprises a vertical position of a mask stage in the inspection apparatus relative to an optical element in the inspection apparatus.

4. The method of claim 1, wherein the inspection parameter comprises a leveling status of a mask stage in the inspection apparatus.

5. The method of claim 1, wherein the inspection parameter comprises a power of a light source in the inspection apparatus.

6. The method of claim 1, further comprising:
after adjusting the inspection parameter, measuring a third reflected light intensity on the mask by the inspection apparatus.

7. The method of claim 6, further comprising:
comparing the first and third reflected light intensities; and
determining whether a second comparison result of the first and third reflected light intensities is acceptable.

8. The method of claim 7, further comprising:
in response to the determination determines that the second comparison result is acceptable, performing an inspection process on the mask by the inspection apparatus.

9. The method of claim 7, further comprising:
in response to the determination determines that the second comparison result is unacceptable, inhibit an inspection recipe of the mask used in the inspection apparatus.

10. The method of claim 7, further comprising:
in response to the determination determines that the second comparison result is unacceptable, adjusting an inspection recipe of the mask used in the inspection apparatus.

11. The method of claim 10, further comprising:
capturing a second reference image of the mask by the inspection apparatus using the adjusted inspection recipe.

12. A method, comprising:
measuring a first reflected light intensity of a light calibration mark on a mask by an inspection apparatus;
after measuring the first reflected light intensity, guiding a light in an exposure system using the mask;
after guiding the light in the exposure system, measuring a second reflected light intensity of the light calibration mark on the mask by the inspection apparatus, wherein the mask is supported by a mask stage in a first position as an inspection parameter;
determining whether a first reflection difference between the first and second reflected light intensities is acceptable; and
in response to the determination determines that the first reflection difference is acceptable, performing an inspection process on the mask by the inspection apparatus.

13. The method of claim 12, further comprising:
in response to the determination determines that the first reflection difference is unacceptable, measuring a plurality of third reflected light intensities of the light calibration mark on the mask by the inspection apparatus with the mask stage in a plurality of second positions different than the first position for measuring the second reflected light intensity.

14. The method of claim 13, further comprising:
calculating a plurality of second reflection differences between each of the third reflected light intensities and the first reflected light intensity.

15. The method of claim 14, further comprising:
determining a smallest one of the second reflection differences; and
compensating the first position of the mask stage with the smallest one of the second reflection differences.

16. The method of claim 14, further comprising:
determining whether the second reflection differences are acceptable; and
in response to the determination determines that the second reflection differences are unacceptable, adjusting an inspection recipe of the mask used in the inspection apparatus.

17. A system, comprising:
a mask stage in an inspection apparatus;
a light source over the mask stage;
a reflective optical element between the light source and the mask stage;
a controller initiating a first relative motion between the mask stage and the reflective optical element;
a detector disposed in the inspection apparatus, wherein the detector is configured to capture reflected light intensity on a mark over the mask stage;
an analyzer electrically connected to the detector, wherein the analyzer is configured to generate an adjustment parameter to the controller based on the captured reflected light intensity; and
a first driving element connected to the mask stage, wherein the first driving element is configured to adjust a position of the mask stage in response to the adjustment parameter.

18. The system of claim 17, wherein the first relative motion initiated by the controller includes moving the mask stage vertically.

19. The system of claim 17, wherein the controller initiates a power variation on the light source, the power variation allowing a variation of the reflected light intensity on the mark.

20. The system of claim 17, further comprising:
a lens in the inspection apparatus; and
a second driving element connected to the lens, wherein the controller initiates a second relative motion between the lens and the light source through the second driving element.
